(19) United States
(12) Patent Application Publication
(10) Pub. No.: US 2023/0189670 A1
(43) Pub. Date: Jun. 15, 2023

(54) ELECTRODE RECESSED PHASE CHANGE MEMORY PORE CELL

(71) Applicant: International Business Machines Corporation, Armonk, NY (US)

(72) Inventors: Fabio Carta, Pleasantville, NY (US); Chung Hon Lam, Peekskill, NY (US); Wanki Kim, Chappaqua, NY (US); Robert L. Bruce, White Plains, NY (US)

(21) Appl. No.: 17/546,178

(22) Filed: Dec. 9, 2021

(51) Int. Cl. H01L 45/00; H01L 27/24

(52) U.S. Cl. CPC H01L 45/1253; H01L 27/2436; H01L 45/06; H01L 45/144; H01L 45/1608

(57) ABSTRACT

A memory cell with a recessed bottom electrode and methods of forming the memory cell are described. A bottom electrode can be deposited on a layer of a structure. A first insulator and a second insulator can be deposited on top of the bottom electrode. The first insulator and the second insulator can be spaced apart from one another to form an opening on top of the bottom electrode. A recess can be etched in the bottom electrode. The recess can be etched in a portion of the bottom electrode that is underneath the opening. The recess and the opening can form a pore. Phase change material can be deposited in the pore to form a memory cell.

### BACKGROUND

The present disclosure relates in general to semiconductor devices and methods of manufacturing semiconductor devices and, in particular, to phase change memory devices with recessed bottom electrode.

Phase change materials can change phase between an amorphous state and a crystalline state by application of specific levels of electrical current or voltage. The amorphous state can be characterized by a relatively higher electrical resistivity than the crystalline state, causing different levels of voltages or current being used for setting the phase of the phase change material. A phase change memory element can use phase change material to increase memory capacity. In an aspect, the different voltage or current levels being applied to change phase among an off state (e.g., no voltage or current applied), the amorphous state, the crystalline state, and different types of the crystalline state, can cause the phase change memory to represent more than two values (e.g., binary) of data that can be stored in a phase change memory element.

### SUMMARY

In one embodiment, a semiconductor structure is generally described. The semiconductor structure can include a bottom electrode including a recess. The semiconductor device can further include a memory cell. A portion of the memory cell can be located within the recess of the bottom electrode.

In one embodiment, a method for forming a memory cell is generally described. The method can include depositing a bottom electrode on a layer of a structure. The method can further include depositing a first insulator and a second insulator on top of the bottom electrode. The first insulator and the second insulator can be spaced apart from one another to form an opening on top of the bottom electrode. The method can further include etching a recess in the bottom electrode. The recess can be etched in a portion of the bottom electrode that is underneath the opening, and the recess and the opening form a pore. The method can further include depositing phase change material in the pore to form a memory cell.

In one embodiment, a memory device is generally described. The memory device can include a first decoder, a second decoder, a plurality of memory elements, a plurality of bit lines connecting the plurality of memory elements to the first decoder, and a plurality of word lines connecting the plurality of memory elements to the second decoder. Each memory element among the plurality of memory elements can include a bottom electrode including a recess. Each memory element can further include a memory cell, where a portion of the memory cell can be located within the recess of the bottom electrode.

Further features as well as the structure and operation of various embodiments are described in detail below with reference to the accompanying drawings. In the drawings, like reference numbers indicate identical or functionally similar elements.

### BRIEF DESCRIPTION OF THE DRAWINGS

FIG. 1 is a cross sectional view of an exemplary structure 100 that can be used for forming an electrode recessed phase change memory pore cell in one embodiment.

FIG. 2 is a cross sectional view of a structure formed after formation of one or more pores in the exemplary structure of FIG. 1 in one embodiment.

FIG. 3 is a cross sectional view of a structure formed after formation of one or more recesses in the exemplary structure of FIG. 2 in one embodiment.

FIG. 4A is a cross sectional view of a structure formed after deposition of phase change material in the exemplary structure of FIG. 3 in one embodiment.

FIG. 4B is a cross sectional view of a structure formed after forming top electrodes in the exemplary structure of FIG. 4A in one embodiment.

FIG. 5A is a cross sectional view of a structure formed after deposition one or more metal liners in the exemplary structure of FIG. 3 in one embodiment.

FIG. 5B is a cross sectional view of a structure formed after deposition of phase change material in the exemplary structure of FIG. 5A in one embodiment.

FIG. 5C is a cross sectional view of a structure formed after forming top electrodes in the exemplary structure of FIG. 5B in one embodiment.

FIG. 6A is a cross sectional view of a structure formed after deposition one or more metal liners in the exemplary structure of FIG. 2 in one embodiment.

FIG. 6B is a cross sectional view of a structure formed after formation of one or more recesses in the exemplary structure of FIG. 6A in one embodiment.

FIG. 6C is a cross sectional view of a structure formed after deposition of phase change material in the exemplary structure of FIG. 6B in one embodiment.

FIG. 6D is a cross sectional view of a structure formed after forming top electrodes in the exemplary structure of FIG. 6C in one embodiment.

FIG. 7 is a diagram illustrating an example device that includes electrode recessed phase change memory pore cells in one embodiment.

FIG. 8 is a flow diagram illustrating a method of forming an electrode recessed phase change memory pore cell in one embodiment.

### DETAILED DESCRIPTION

The present application will now be described in greater detail by referring to the following discussion and drawings that accompany the present application. It is noted that the drawings of the present application are provided for illustrative purposes only and, as such, the drawings are not drawn to scale. It is also noted that like and corresponding elements are referred to by like reference numerals.

In the following descriptions, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

It will also be understood that when an element such as a layer, region or substrate is referred to as being “on” or “over” another element, it can be directly on the other element or intervening elements can also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

In an aspect, phase change memory (PCM) cells formed inside a pore (e.g., confined PCM cells), can provide relatively small pore structure and high current density inside the pore. Further, PCM cells formed inside the pore can enable almost complete elemental segregation, or phase segregation, during a number of initial cycles (e.g., the first few set-reset cycles). Phase segregation can cause metallic elements in the PCM cell to move toward a bottom electrode and a top electrode, effectively forming an extended metallic region that can connect a switching region of the PCM cell to the metal plug of the bottom electrode to access devices underneath the bottom electrode. As a result of this extended metallic region, the switching region of the PCM cell can be located toward a center of the pore, and a composition of the phase change material forming the PCM cell can remain stable throughout a lifetime of the PCM cell, providing relatively good memory cell endurance.

However, during cell programming of the PCM cell, the current being delivered to the PCM cell can be dissipated through heat in the extended metal region. This current dissipation can reduce a power efficiency (e.g., increase power consumption) of the PCM cell, and can limit an amount of reset current reduction of the PCM cell. The methods described herein can provide a structure and method for forming a PCM cell with recessed electrode, where the recessed electrode is a bottom electrode of the PCM cell. The recessed portion of the PCM cell can accommodate a part of the metal extended region of the PCM cell. The part of the metal extended region of the PCM cell that is located within the recessed portion of the bottom electrode can reduce power dissipation at portions of the PCM cell that are outside of the switching region of the PCM cell.

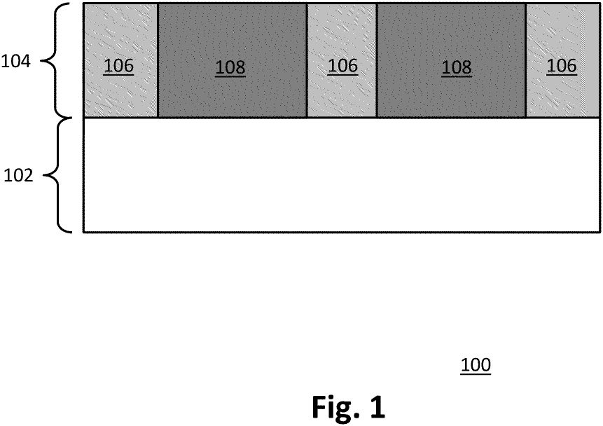

FIG. 1 is a cross sectional view of an exemplary structure 100 that can be used for forming an electrode recessed phase change memory pore cell in one embodiment. The structure 100 can be a deposition stack including device layer 102 and a bottom electrode layer 104. The device layer 102 can include, front end of line (FEOL) devices and components, and back end of line (BEOL) devices and interconnects. For example, the FEOL devices and components in the device layer 102 can include transistors (e.g., field-effect transistors (FETs)), resistors, capacitors, and/or other types of FEOL devices. The BEOL devices and interconnects can include metal layers, metal interconnects, vias (e.g., through silicon via (TSV)), and/or other types of BEOL devices. The bottom electrode layer 104 can include one or more insulators 106 and one or more metal plugs 108. The insulators 106 can be composed of dielectric materials, such as silicon nitride, silicon carbide nitride, or other types of dielectric materials. The metal plugs 108 can be composed of metal such as graphite, copper, copper tungsten, or other metal suitable for forming an electrode that connects to the devices in the device layer 102.

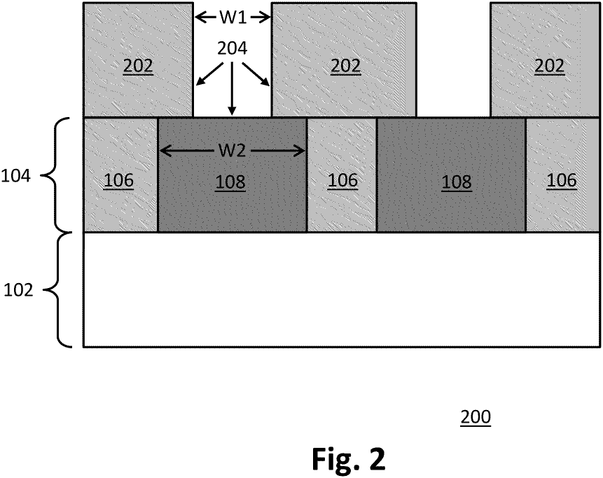

FIG. 2 is a cross sectional view of a structure 200 formed after formation of one or more pores in the exemplary structure 100 of FIG. 1 in one embodiment. In one embodiment, the structure 100 in FIG. 1 can undergo a deposition process to form one or more openings 204 on top of the bottom electrode layer 104. In one embodiment, one or more insulators 202 can be deposited on top of the bottom electrode layer 104. The insulators 202 can be composed of dielectric materials, such as silicon nitride, silicon carbide nitride, or other types of dielectric materials. The deposited insulators 202 can be spaced apart by a distance W1, where W1 can also be a width of the opening 204. In one embodiment, the width W1 of the opening 204 can be less than a width W2 of the metal plug 108.

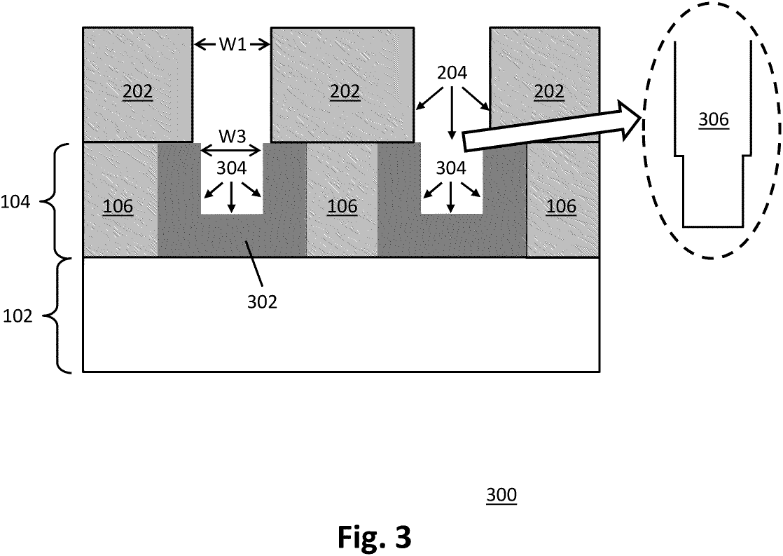

FIG. 3 is a cross sectional view of a structure 300 formed after formation of one or more recesses in the exemplary structure 200 of FIG. 2 in one embodiment. In one embodiment, the structure 200 in FIG. 2 can undergo an etching process to form one or more recesses 304 in the metal plug 108 shown in FIG. 1 and FIG. 2. A top surface of the metal plug 108 that is exposed to the opening 204 can be etched to form the recess 304. In response to the formation of a recess 304, a bottom electrode 302 including the recess 304 is formed in the bottom electrode layer 104. In one embodiment, a width W3 of the recess 304 can be equal to or less than the width W1 of the opening 204 shown in FIG. 2. A combination of the opening 204 and the recess 304 can be referred to as a pore 306.

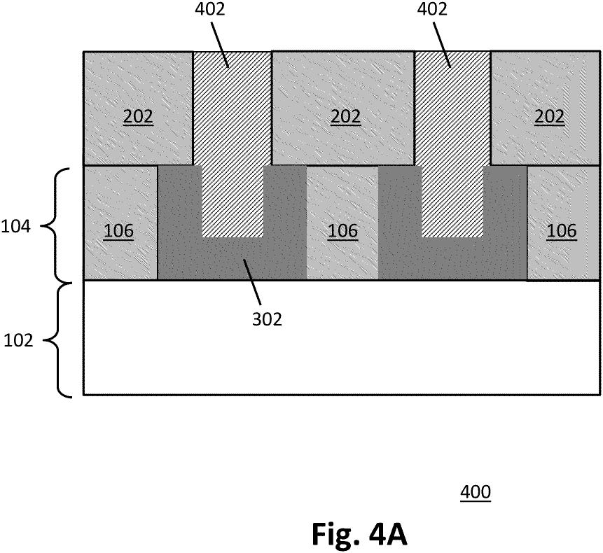

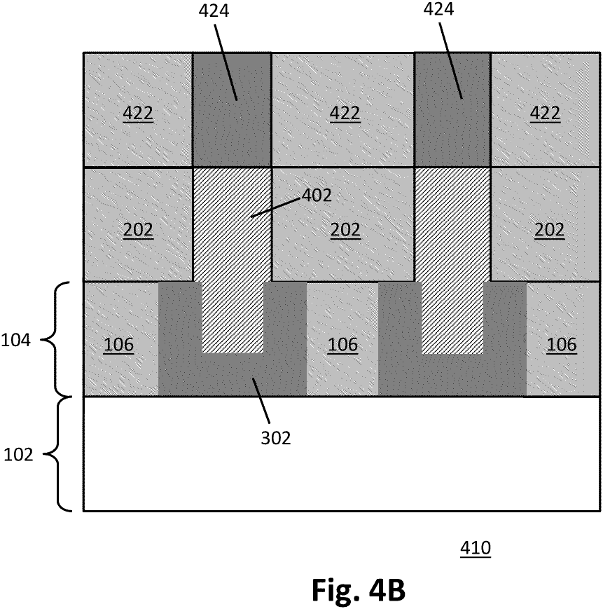

FIG. 4A is a cross sectional view of a structure 400 formed after deposition of phase change material in the exemplary structure 300 of FIG. 3 in one embodiment. In one embodiment, the structure 300 in FIG. 3 can undergo a deposition process to deposit phase change material into one or more pores 306 shown in FIG. 3, where each pore 306 includes the opening 204 shown in FIG. 2 and the recess 304 shown in FIG. 3. In one or more embodiments, the phase change material being deposited into the pores 306 can be, for example, germanium-antimony-tellurium (GST). In response to the deposition process, one or more phase change memory (PCM) cells 402 can be formed. In response to forming the PCM cells 402, reactive ion etching (RIE) and/or chemical mechanical polishing (CMP) processes can be performed to planarize a top surface of the PCM cells 402 and to align the top surface of the PCM cells 402 with the top surface of the insulators 202.

FIG. 4B is a cross sectional view of a structure 410 formed after forming top electrodes in the exemplary structure 400 of FIG. 4A in one embodiment. In one embodiment, the structure 400 in FIG. 4A can undergo a deposition process to deposit one or more insulators 422 on top of the insulators 202, and one or more metal plugs 424 on top of the PCM cells 402. The insulators 422 can be composed of dielectric materials, such as silicon nitride, silicon carbide nitride, or other types of dielectric materials. The metal plugs 424 can be top electrodes connecting the PCM cells 402 to devices that can be formed on top of the structure 410. In response to depositing the insulators 422 and the metal plugs 424, CMP process can be performed to planarize a top surface of the metal plugs 424 to align the top surface of the metal plugs 424 with the insulators 422.

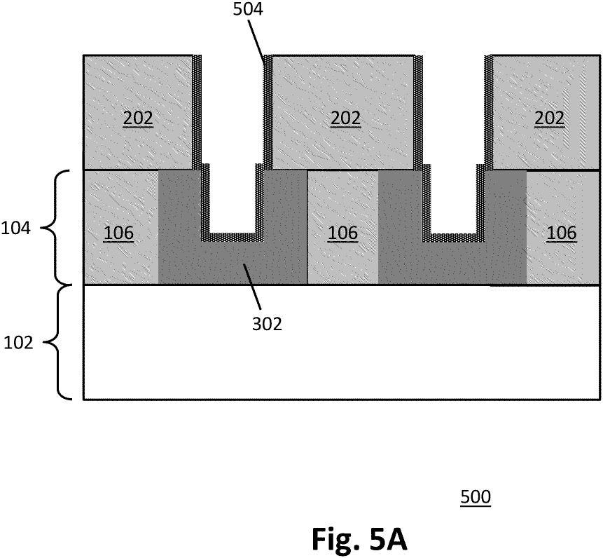

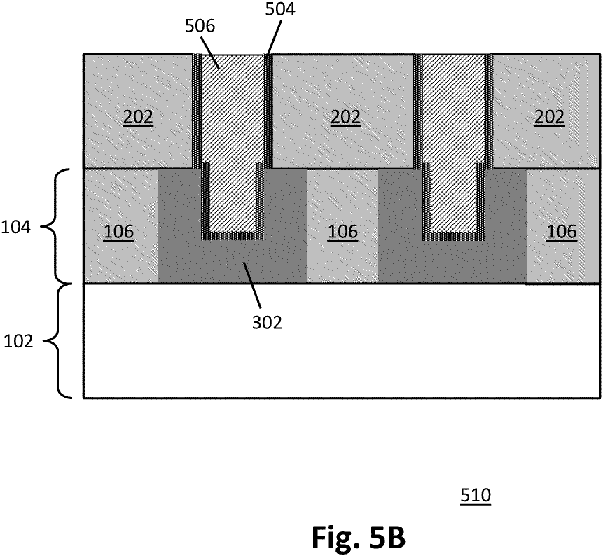

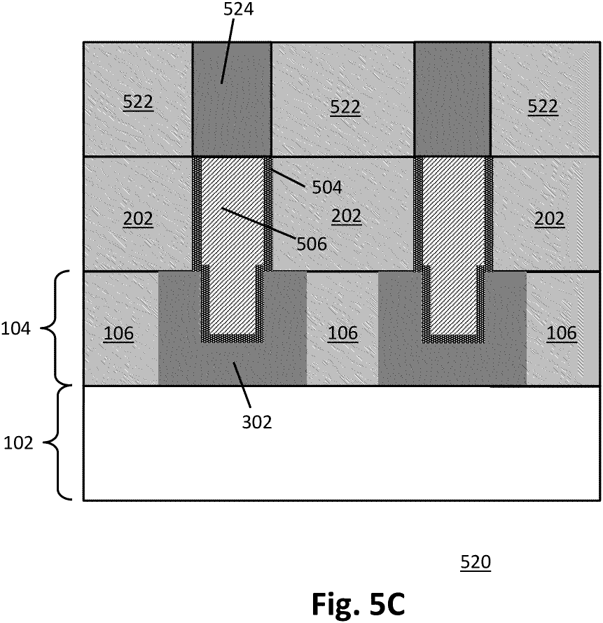

FIG. 5A is a cross sectional view of a structure formed after deposition one or more metal liners in the exemplary structure 300 of FIG. 3 in one embodiment. In one embodiment, the structure 300 in FIG. 3 can undergo a deposition process to deposit a liner 504 on the sidewalls of the pore 306 shown in FIG. 3. The liner 504 can be, for example, a tantalum nitride (TaN) liner or other types of metal nitride liners or metallic liners. The liner 504 can be deposited to conform to the pore 306 and cover the entire surface of the pore 306. The liner 504 can also be on the sidewalls of the insulators 202.

FIG. 5B is a cross sectional view of a structure 510 formed after deposition of phase change material in the exemplary structure 500 of FIG. 5A in one embodiment. In one embodiment, the structure 500 in FIG. 5A can undergo a deposition process to deposit phase change material into the pore 306 (see FIG. 3) with the liner 504, where each pore 306 includes the opening 204 shown in FIG. 2 and the recess 304 shown in FIG. 3. In one or more embodiments, the phase change material being deposited into the pores 306 can be, for example, germanium-antimony-tellurium (GST). In response to the deposition process, one or more phase change memory (PCM) cells 506 can be formed. In response to forming the PCM cells 506, reactive ion etching (RIE) and/or chemical mechanical polishing (CMP) processes can be performed to planarize a top surface of the PCM cells 506 and to align the top surface of the PCM cells 506 with the top surface of the insulators 202.

FIG. 5C is a cross sectional view of a structure 520 formed after forming top electrodes in the exemplary structure 510 of FIG. 5B in one embodiment. In one embodiment, the structure 510 in FIG. 4B can undergo a deposition process to deposit one or more insulators 522 on top of the insulators 202, and one or more metal plugs 524 on top of the PCM cells 506 and the liner 504. The insulators 522 can be composed of dielectric materials, such as silicon nitride, silicon carbide nitride, or other types of dielectric materials. The metal plugs 524 can be top electrodes connecting the PCM cells 506 to devices that can be formed on top of the structure 520. In response to depositing the insulators 522 and the metal plugs 524, CMP process can be performed to planarize a top surface of the metal plugs 524 to align the top surface of the metal plugs 524 with the insulators 522.

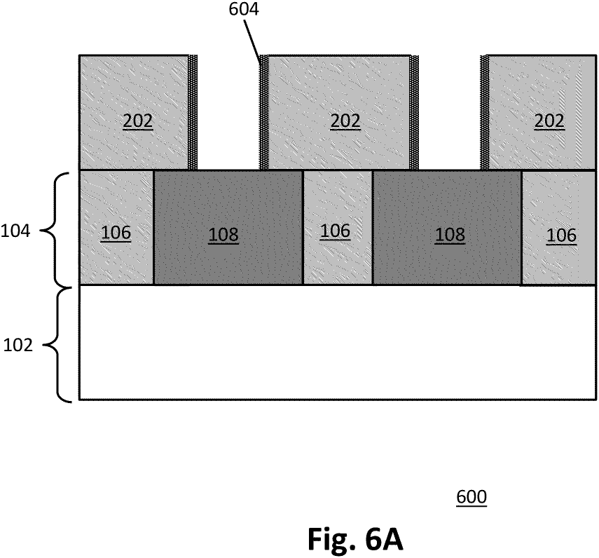

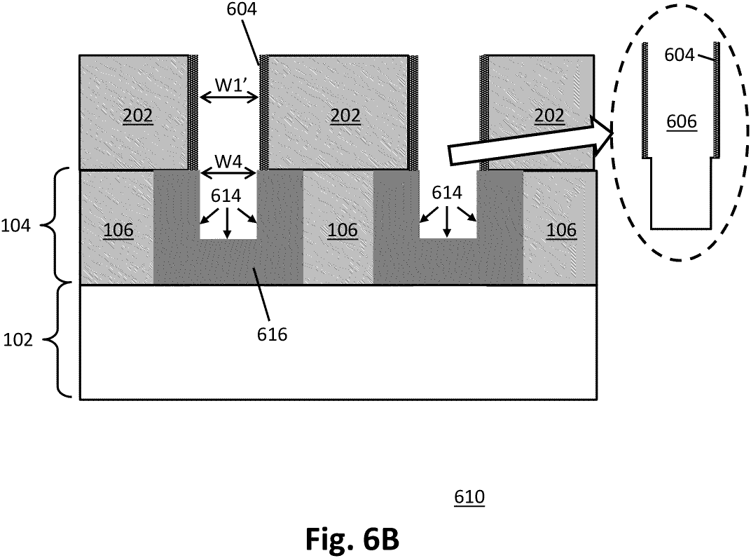

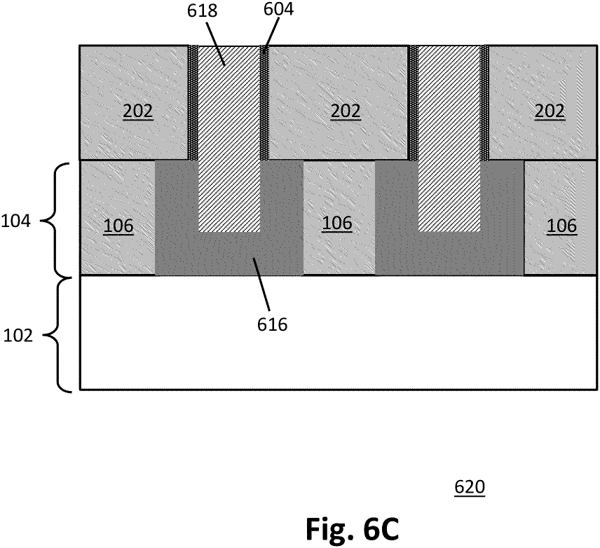

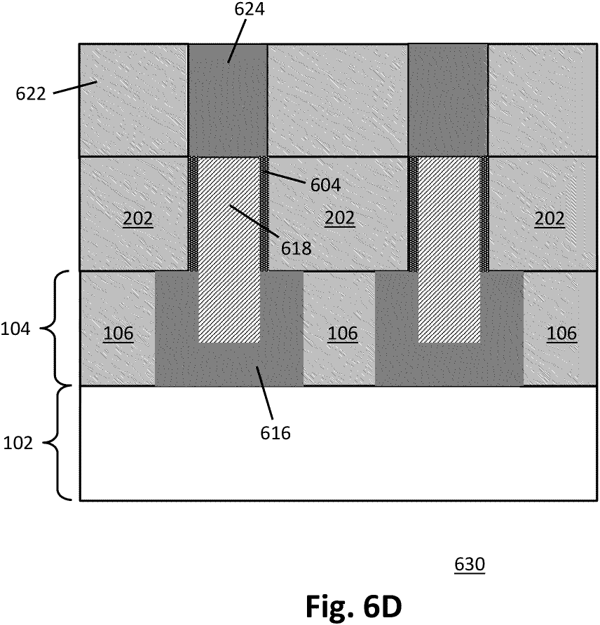

FIG. 6A is a cross sectional view of a structure 600 formed after deposition one or more metal liners in the exemplary structure 200 of FIG. 2 in one embodiment. In one embodiment, the structure 200 in FIG. 2 can undergo a deposition process to deposit a liner 604 on the sidewalls of each opening 204 shown in FIG. 2. The liner 604 can be, for example, a tantalum nitride (TaN) liner or other types of metal nitride liners or metallic liners. The liner 604 can be deposited on the sidewalls of the insulators 202. The deposition of the liner 604 can decrease the width W1 of the opening 204 to W1′.

FIG. 6B is a cross sectional view of a structure 610 formed after formation of one or more recesses in the exemplary structure 600 of FIG. 6A in one embodiment. In one embodiment, the structure 600 in FIG. 6A can undergo an etching process to form one or more recesses 614 in the metal plug 108 shown in FIG. 1 and FIG. 2. A top surface of the metal plug 108 that is exposed to the opening 204 can be etched to form the recess 614. In response to the formation of a recess 614, a bottom electrode 616 including the recess 614 is formed in the bottom electrode layer 104. In one embodiment, a width W4 of the recess 614 can be equal to or less than the width W1′ of the opening 204 with the liner 604. A combination of the opening 204 with the liner 604 and the recess 614 can be referred to as a pore 606.

FIG. 6C is a cross sectional view of a structure formed after deposition of phase change material in the exemplary structure 610 of FIG. 6B in one embodiment. In one embodiment, the structure 610 in FIG. 6B can undergo a deposition process to deposit phase change material into the pore 606 (see FIG. 6B) with the liner 604, where each pore 606 includes the opening 204 with the liner 604 (see FIG. 6A) and the recess 614 shown in FIG. 6B. In one or more embodiments, the phase change material being deposited into the pores 606 can be, for example, germanium-antimony-tellurium (GST). In response to the deposition process, one or more phase change memory (PCM) cells 618 can be formed. In response to forming the PCM cells 618, reactive ion etching (RIE) and/or chemical mechanical polishing (CMP) processes can be performed to planarize a top surface of the PCM cells 618 and to align the top surface of the PCM cells 618 with the top surface of the insulators 202.

FIG. 6D is a cross sectional view of a structure 630 formed after forming top electrodes in the exemplary structure 620 of FIG. 6C in one embodiment. In one embodiment, the structure 620 in FIG. 6C can undergo a deposition process to deposit one or more insulators 622 on top of the insulators 202, and one or more metal plugs 624 on top of the PCM cells 618 and the liner 604. The insulators 622 can be composed of dielectric materials, such as silicon nitride, silicon carbide nitride, or other types of dielectric materials. The metal plugs 624 can be top electrodes connecting the PCM cells 618 to devices that can be formed on top of the structure 630. In response to depositing the insulators 622 and the metal plugs 624, CMP process can be performed to planarize a top surface of the metal plugs 624 to align the top surface of the metal plugs 624 with the insulators 622.

As a result of forming PCM cells having a portion inside a recess of a bottom electrode, a metal extended region of the PCM cell can reduce power dissipation at portions of the PCM cell that are outside of the switching region of the PCM cell. Using FIG. 3 to FIG. 4B as an example, a first portion of the PCM cell 402 can be located inside the recess 304, and a second portion of the PCM cell 402 can be located outside of the recess 304 and between the insulators 202. The first portion of the PCM cell 402 may dissipate less current or power due to the first portion being exposed to, or being in contact with, additional metallic cross section (e.g., surfaces of the recess 304 of the bottom electrode 302). Current in the second portion of the PCM cell 402 will experience more resistance when compared to current in the first portion of the PCM cell 402, due to the additional metallic cross section provided by the recess 304. The higher resistance in the second portion of the PCM cell 402 (e.g., outside of recess 304, between insulators 202) can increase an amount of heat in a switching region, or nearby the switching region, of the PCM cell 402.

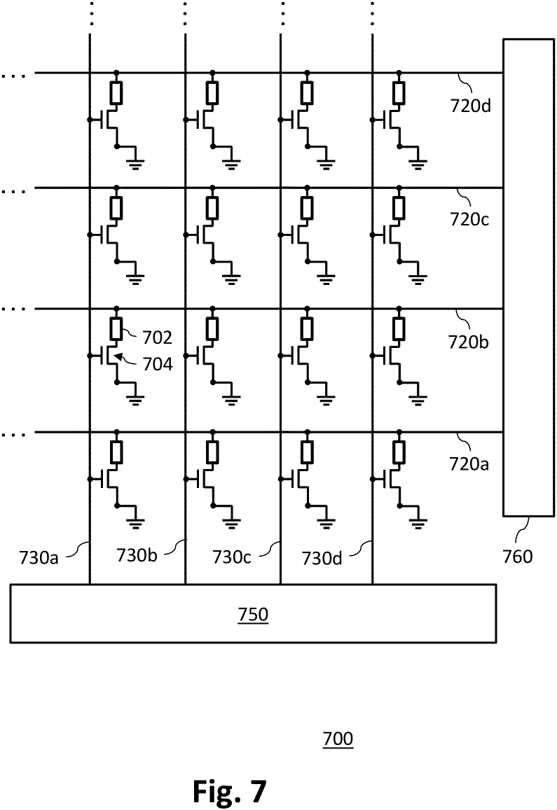

FIG. 7 is a diagram illustrating an example device that includes electrode recessed phase change memory pore cells in one embodiment. In one embodiment, a portion of a phase change memory device 700 can include a plurality of phase change memory elements, each phase change memory element can include a phase change memory cell 702 and a transistor 704. The phase change memory cell 702 can be, for example, one of the PCM cells 402, 506, 628 shown in FIG. 4A to FIG. 6D. In one embodiment, the transistor 704 can be a field effect transistor (FET) with vertical channels within the device layer 102 shown in FIG. 1 to FIG. 6D. The input and output of each phase change memory element are the gate and drain terminals of the transistor 704, respectively. In one embodiment, the transistors 704 can be arranged in a common source configuration, where the source terminal of the transistor 704 is coupled to a common voltage. In another embodiment, the source terminal of the transistor 704 can be coupled to ground. A plurality of word lines, such as 730a, 730b, 730c, 730d, can connect the gate terminals of the transistors 704 to a decoder 750. A plurality of bit lines, such as 720a, 720b, 720c, 720d, can connect the phase change memory cells 702 to a decoder 760. Reading or writing to phase change memory cells of the device 700 can be achieved by applying an appropriate voltage or current to corresponding word lines and another appropriate voltage or current to corresponding bit lines to induce a current through the phase change memory elements. The level and duration of the voltages or currents being applied is dependent upon the operation performed, such as a reading operation or a writing operation.

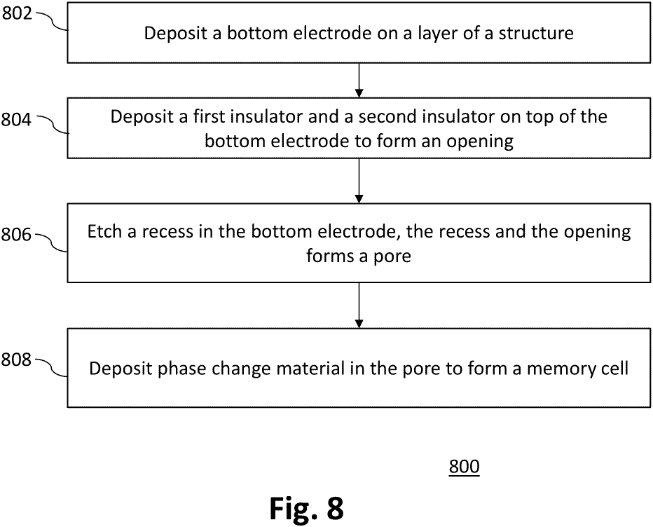

FIG. 8 is a flow diagram illustrating a method of forming an electrode recessed phase change memory pore cell in one embodiment. An example process 800 may include one or more operations, actions, or functions as illustrated by one or more of blocks 802, 804, 806, and/or 808. Although illustrated as discrete blocks, various blocks can be divided into additional blocks, combined into fewer blocks, eliminated, performed in different order, or performed in parallel, depending on the desired implementation.

The process 800 can be performed to form a memory cell in a memory device. The process 800 can begin at block 802. At block 802, a bottom electrode can be deposited on a first layer of a substrate. The process 800 can proceed to block 804 from block 802. At block 804, a first insulator and a second insulator can be deposited on top of the bottom electrode to form an opening on top of the bottom electrode. The first insulator and the second insulator can be spaced apart from one another to form an opening on top of the bottom electrode. In one embodiment, a metal liner can be deposited on sidewalls of the opening prior to etching the recess.

The process 800 can proceed to block 806 from block 804. At block 806, a recess can be etched in the bottom electrode. The recess can be etched in a portion of the bottom electrode that is underneath the opening. The recess and the opening can form a pore. In one embodiment, a width of the opening can be greater than a width of the recess. In one embodiment, a metal liner can be deposited on the pore prior to depositing the phase change materials in the pore.

The process 800 can proceed to block 808 from block 806. At block 808, phase change material can be deposited in the pore to form a memory cell. In one embodiment, the memory cell can be a phase change memory (PCM) cell. In one embodiment, a top electrode can be deposited on top of the memory cell. In one embodiment, a chemical mechanical polishing (CMP) process can be performed to planarize a top surface of the memory cell. In one embodiment, depositing the phase change material can include depositing germanium-antimony-tellurium (GST).

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more instructions for implementing the specified logical function(s). In some alternative implementations, the functions noted in the blocks may occur out of the order noted in the Figures. For example, two blocks shown in succession may, in fact, be performed substantially concurrently, or the blocks may sometimes be performed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements, if any, in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

What is claimed is:

1. A semiconductor structure comprising:
a bottom electrode including a recess; and
a memory cell, wherein a portion of the memory cell is located within the recess of the bottom electrode.

2. The semiconductor structure of claim 1, wherein the memory cell is a phase change memory (PCM) cell.

3. The semiconductor structure of claim 1, wherein the portion of the memory cell is a first portion of the memory cell, and the semiconductor structure further comprises:
a first layer including the bottom electrode and the first portion of the memory cell;
a second layer on top of the first layer, the second layer including a second portion of the memory cell; and
a third layer on top of the second layer, the third layer including a top electrode connected to the memory cell.

4. The semiconductor structure of claim 3, wherein a metal liner is deposited on sidewalls of the second portion of the memory cell.

5. The semiconductor structure of claim 3, wherein the second layer further comprises a first insulator and a second insulator, and the second portion of the memory cell is between the first insulator and the second insulator.

6. The semiconductor structure of claim 1, wherein a metal liner is deposited on sidewalls of the memory cell.

7. A method for forming a memory cell, the method comprising:
depositing a bottom electrode on a layer of a structure;
depositing a first insulator and a second insulator on top of the bottom electrode, the first insulator and the second insulator being spaced apart from one another to form an opening on top of the bottom electrode;
etching a recess in the bottom electrode, wherein the recess is etched in a portion of the bottom electrode that is underneath the opening, and the recess and the opening form a pore; and
depositing phase change material in the pore to form a memory cell.

8. The method of claim 7, wherein the memory cell is a phase change memory (PCM) cell.

9. The method of claim 7, further comprising depositing a top electrode on top of the memory cell.

10. The method of claim 7, wherein a width of the opening is greater than a width of the recess.

11. The method of claim 7, further comprising performing a chemical mechanical polishing (CMP) process to planarize a top surface of the memory cell.

12. The method of claim 7, further comprising depositing a metal liner on sidewalls of the opening prior to etching the recess.

13. The method of claim 7, further comprising depositing a metal liner on the pore prior to depositing the phase change materials in the pore.

14. The method of claim 7, wherein depositing the phase change material comprises depositing germanium-antimony-tellurium (GST).

15. A memory device comprising:
a first decoder;
a second decoder;
a plurality of memory elements;
a plurality of bit lines connecting the plurality of memory elements to the first decoder;
a plurality of word lines connecting the plurality of memory elements to the second decoder;
wherein each memory element among the plurality of memory elements comprises:
a bottom electrode including a recess; and
a memory cell, wherein a portion of the memory cell is located within the recess of the bottom electrode.

16. The memory device of claim 15, wherein the memory cell is a phase change memory (PCM) cell.

17. The memory device of claim 15, wherein the portion of the memory cell is a first portion of the memory cell, and each memory element further comprises:
a first layer including the bottom electrode and the first portion of the memory cell;
a second layer on top of the first layer, the second layer including a second portion of the memory cell; and
a third layer on top of the second layer, the third layer including a top electrode connected to the memory cell.

18. The memory device of claim 17, wherein a metal liner is deposited on sidewalls of the second portion of the memory cell.

19. The memory device of claim 17, wherein the second layer further comprises a first insulator and a second insulator, and the second portion of the memory cell is between the first insulator and the second insulator.

20. The memory device of claim 15, wherein a metal liner is deposited on sidewalls of the memory cell.
